(19) United States
(12) Patent Application Publication
(10) Pub. No.: US 2008/0283812 A1
(43) Pub. Date: Nov. 20, 2008

(54) PHASE-CHANGE MEMORY ELEMENT

(75) Inventor: Michael Y. Liu, Chiayi City (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/961,452

(22) Filed: Dec. 20, 2007

(30) Foreign Application Priority Data
May 16, 2007 (TW) TW96117359

(51) Int. Cl. H01L 45/00

(52) U.S. Cl. 257/2; 257/E45.002

(57) ABSTRACT

A phase-change memory element. The phase-change memory comprises first and second electrodes. A phase-change material layer is formed between the first and second electrodes. And a carbon-doped oxide dielectric layer is formed to surround the phase-change material layer, wherein the first electrode electrically connects the second electrodes via the phase-change material layer.

### BACKGROUND OF THE INVENTION

1. Field of the Invention

The invention relates to a memory element, and more particularly to a phase-change memory element and method for fabricating the same.

2. Description of the Related Art

Most electronic devices use different types of memories, such as DRAM, SRAM and flash memory or a combination based on application requirements, operating speed, memory size and cost considerations of the devices. Current new developments in the memory technology field include FeRAM, MRAM and phase-change memory. Among the memories, phase-change memory is most likely to be mass-produced in the near future.

Phase-change memory is characterized by being non-volatile, having low power consumption and having high density, contrast, and cycling, thus, is increasingly being applied in the semiconductor industry. Phase-change memories can be fabricated using a CMOS process, as a detached memory cell or an embedded memory cell.

Storing data in a phase-change memory element typically requires high current density. Unfortunately, high current can lead to unwanted high power consumption. Increasing the contact resistance between the phase-change layer and the contact is a way to reduce the power consumption. Many methods for reducing area of the contacts have been proposed to increase the resistance and reduce the power consumption. Yet, as PRAMs (Phase-change RAMs) become smaller, forming small contacts to the phase-change layer pattern has generally become increasingly difficult. This difficulty arises because the reduction of design rules limit photolithography processes for defining contact images on photoresist layers. Furthermore, limitations to the photolithography process may decrease the flexibility of the PRAM fabrication processes.

In order to reduce programming current, the most straightforward way is to shrink the heating area. A benefit of this strategy is simultaneous reduction of cell size. Assuming a fixed required current density, the current will shrink in proportion to the area. In reality, however, cooling becomes significant for smaller structures, and heat loss to surrounding areas becomes more important due to increasing surface/volume ratio. As a result, the required current density must increase as heating area shrinks. This poses an electromigration concern for reliability. Hence, it is important to use materials in the cell which do not pose an electromigration concern. It is also important to improve the heating efficiency, by increasing heating flux in the active programming region while reducing heat loss to surrounding areas.

The heating loss is proportional to the thermal conductivity of surrounding areas dielectric material. As a reference, the thermal conductivity of a commonly used phase-change chalcogenide, Ge2Sb2Te5, is experimentally measured to have a range of values, averaging around a value of 0.3 W/m-K. The low conductivity is due to both low electron density and vacancies in the microstructure which enhance phonon scattering. Since it is the active material, it obviously cannot serve as surrounding areas dielectric. Silicon nitride and silicon oxide are stable when contacted with the chalcogenide. However, their thermal conductivities exceed 1 W/m-K, which prohibits scaling down the programming current beyond the current state-of-the-art.

One solution uses a mixture of the low thermal conductivity chalcogenide material with a stable higher thermal conductivity dielectric, such that the effective thermal conductivity of the mixture approaches that of the chalcogenide.

U.S. Pat. No. 5,933,365 “Memory element with energy control mechanism” discloses the use of thermal isolation layers which at least partially encapsulate the phase-change material. However, the selection of candidate materials far exceeds the range of materials available for state-of-the-art memory cell fabrication, and do not reflect the currently known thermal conductivities of such materials.

Therefore, it is necessary to develop a phase-change memory to solve the previously described problems.

### BRIEF SUMMARY OF THE INVENTION

An exemplary embodiment of a phase-change memory element comprises a first electrode and a second electrode. A first phase-change material layer is formed between the first electrode and the second electrode, wherein the first electrode electrically connects the second electrodes via the phase-change material layer. A carbon-doped oxide layer covers the side walls of the first phase-change material layer.

According to another embodiment of the invention, the phase-change memory element comprises a bottom electrode and a top electrode. A first phase-change material layer is formed between the bottom electrode and top electrode, wherein the bottom electrode is electrically connected to the top electrode via the first phase-change material layer. A carbon-doped silicon oxide layer is formed to surround the first phase-change material layer and to cover the side walls of the first phase-change material layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1a-1d are cross sections of a method for fabricating a phase-change memory element according to an embodiment of the invention.

FIGS. 2a-2c are cross sections of a method for fabricating a phase-change memory element according to another embodiment of the invention.

FIGS. 3a-3d are cross sections of a method for fabricating a phase-change memory element according to yet another embodiment of the invention.

FIGS. 4-6 are cross sections of phase-change memory elements according to some embodiments of the invention.

### DETAILED DESCRIPTION OF THE INVENTION

The phase-change memory element of the embodiments of the invention has a carbon-doped oxide layer, with low thermal conductivity, covering the side walls of the phase change material, thereby reducing heat loss to surrounding areas. Therefore, the disclosed phase-change memory element allows reduction of both programming current and programming voltage, since the required Joule heating is reduced.

The following description is of the best-contemplated mode of carrying out the invention. This description is made for the purpose of illustrating the general principles of the invention and should not be taken in a limiting sense. The scope of the invention is best determined by reference to the appended claims.

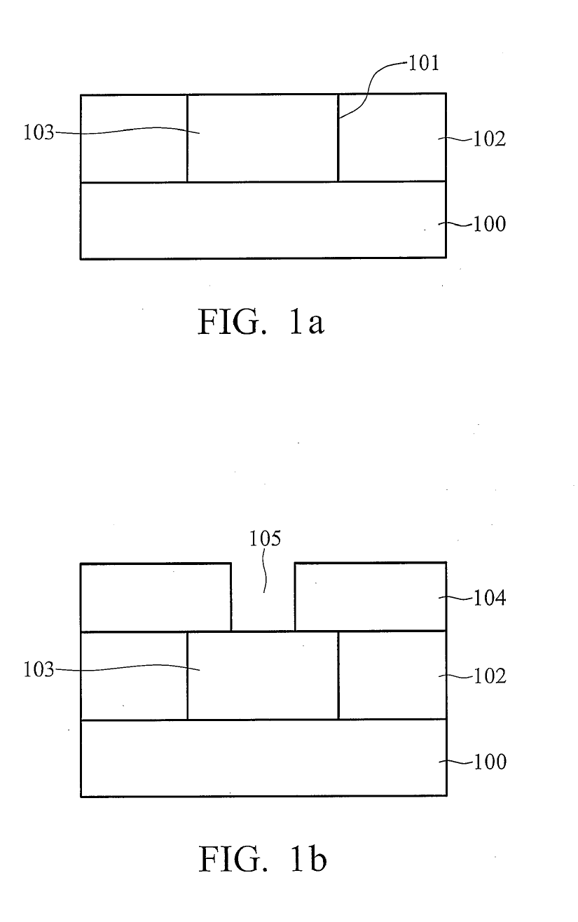

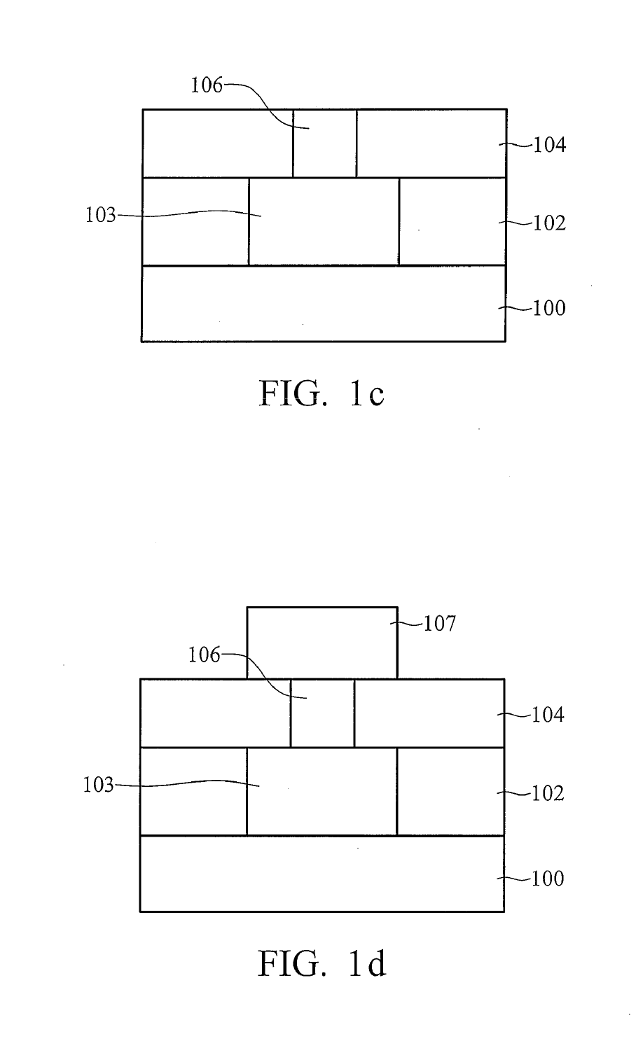

First, referring to FIG. 1a, a substrate 100 is provided, wherein a dielectric layer 102 with a first opening 101 is formed on the substrate 100. Next, a first electrode 103 is formed into the opening 101, wherein the first electrode 103 serves as a bottom electrode of the phase-change memory element. Particularly, the substrate 100 can be a substrate employed in a semiconductor process, such as silicon substrate. The substrate 100 can be a substrate comprising a complementary metal oxide semiconductor (CMOS) circuit, isolation structure, diode, or capacitor. The accompanying drawings show the substrate 100 in a plain rectangle in order to simplify the illustration. Suitable material for the first electrode 103, for example, is TaN, W, TiN, or TiW.

Next, referring to FIG. 1b, a carbon-doped oxide dielectric layer 104 with a second opening 105 is formed on the above structure, wherein the second opening 105 exposes the top surface of the first electrode 103. The carbon-doped oxide dielectric layer 104 has thermal conductivity less than 0.4 W/m-k and can comprise carbon-doped silicon oxide. The method for forming the carbon-doped oxide layer is not limited in the invention and can be any conventional method for forming carbon-doped oxide layer.

Next, referring to FIG. 1c, a phase change material layer 106 is formed into the second opening 105 to directly contact with the first electrode 103. The phase-change material layer comprises chalcogenide such as In, Ge, Sb, Te or combinations thereof, for example GeSbTe or InGeSbTe. It should be noted that the carbon-doped oxide dielectric layer 104 is formed to surround and cover the phase change material layer 106. Since the carbon-doped oxide dielectric layer 104 has low thermal conductivity, the heat loss to surrounding areas from the phase change material layer is reduced. Accordingly, the carbon-doped oxide dielectric layer 104 directly surrounds and completely covers the side walls of phase change material layer 106, exposing the top and bottom surface of the phase change material layer 106 respectively contacting the top and bottom electrodes.

Finally, referring to FIG. 1d, a patterned second electrode 107 is formed on the above structure of FIG. 1c to serve as a top electrode. The second electrode 107 directly contacts to the top surface of the phase change material layer 106. The material of the second electrode 107 can be the same as the first electrode 103 and can be metal or metal alloy, such as TaN, W, TiN, or TiW.

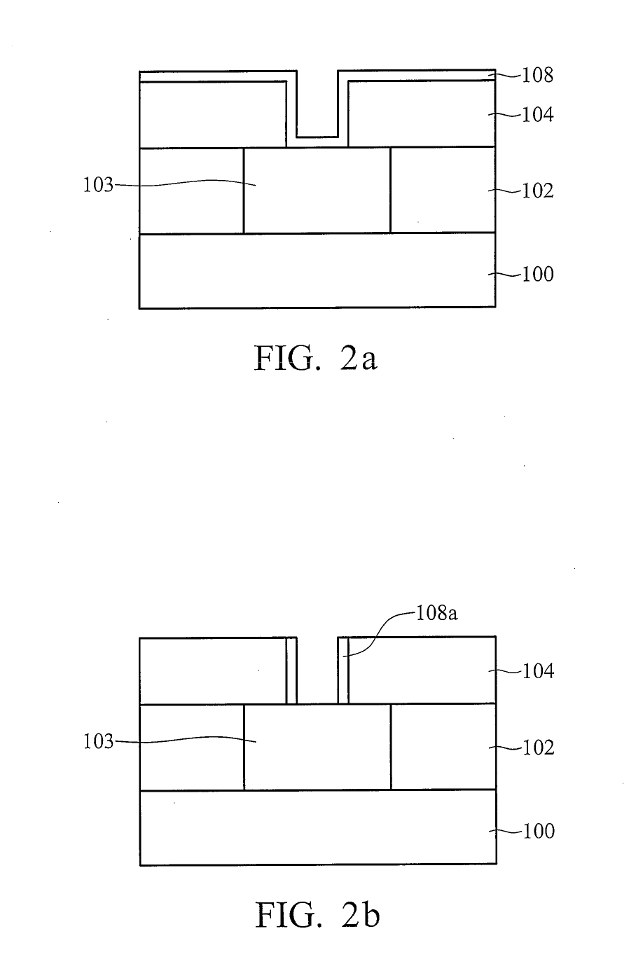

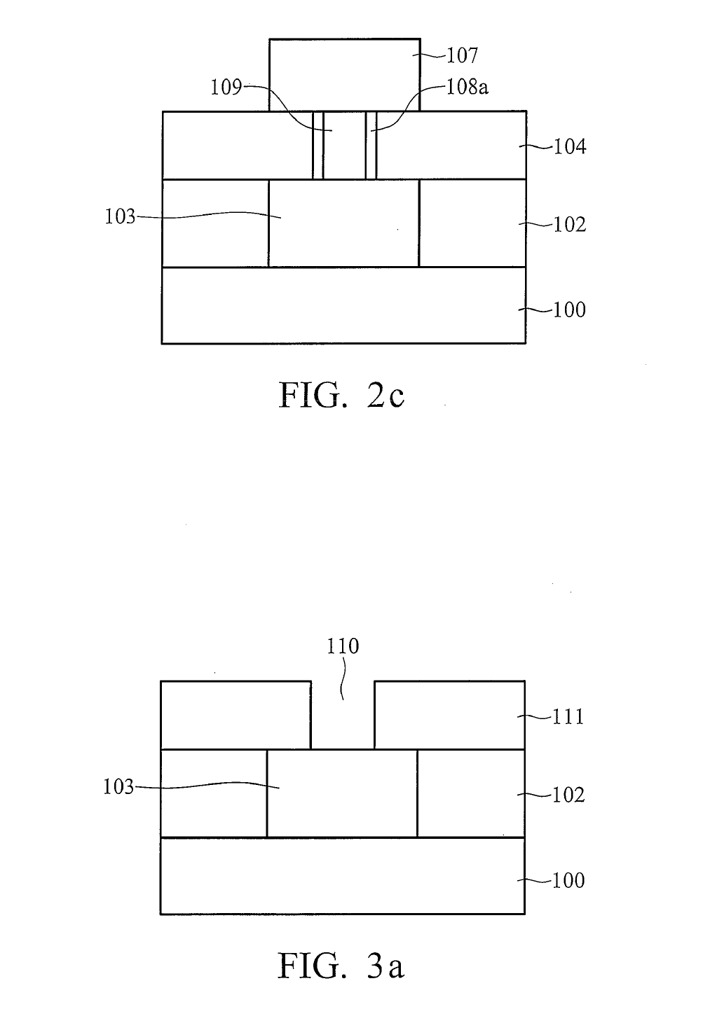

Further, according to another embodiment of the invention, the dimension of the phase change material layer 106 can be less than the resolution limit of photolithography process. Therefore, the contact interface between the first phase-change material layer and the first electrode and the contact interface between the first phase-change material layer and the second electrode can be also less than the resolution limit of photolithography process. After the process as disclosed in FIG. 1b, a thin phase change material layer 108 can be conformally formed on the carbon-doped oxide dielectric layer 104 and the first electrode 103, as shown in FIG. 2a.

Next, referring to FIG. 2b, the phase change material layer 108 is subjected to an isotropic etching process, leaving a phase change material pillar 108a, wherein the contact interface between the phase change material pillar 108a and electrodes (such as first electrode 103 or second electrode 107 formed subsequently) has a dimension less than the resolution limit of photolithography process. Finally, a dielectric layer 109 is formed into an opening between the phase change material pillar 108a, and a second electrode 107 is formed on the dielectric layer 109 to electrically connect to the phase change material pillar 108, as shown in FIG. 2c. Further, the dielectric layer 109 can be a carbon-doped oxide layer to reduce the heat loss.

Moreover, according to yet another embodiment of the invention, the carbon-doped oxide layer can be a liner layer as disclosed below.

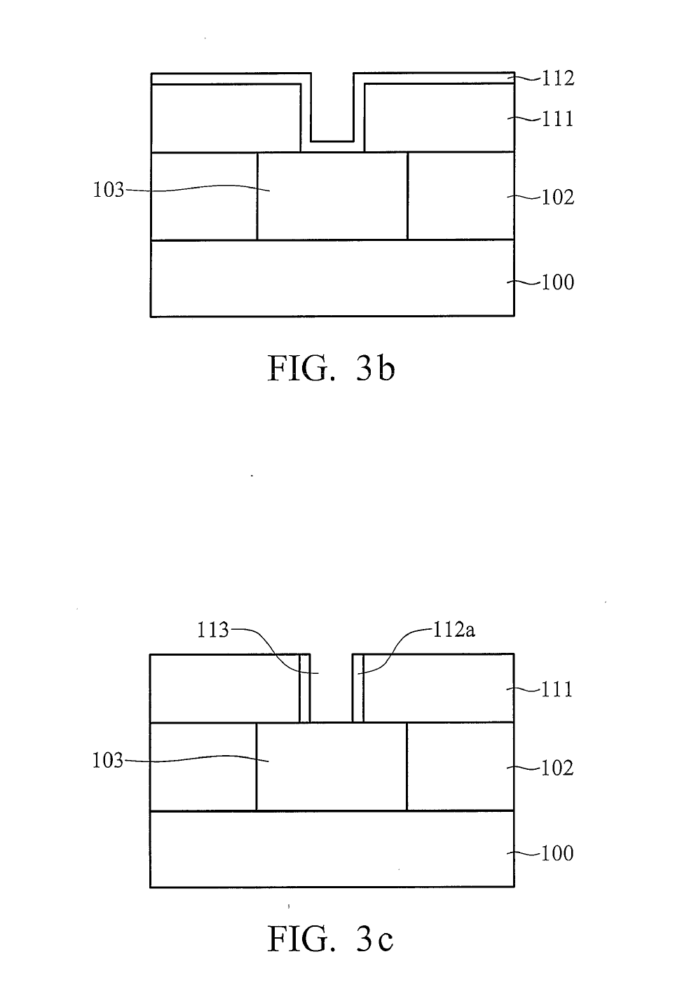

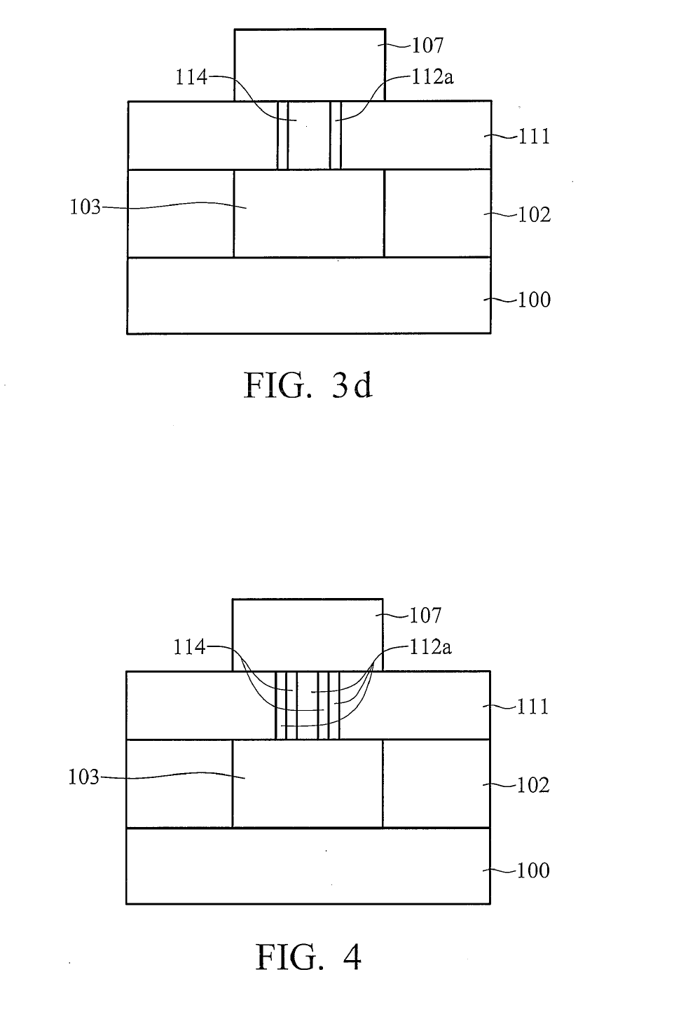

After the process as disclosed in FIG. 1a, a dielectric layer 111 with an opening 110 is formed to expose the top surface of the first electrode 103, as shown in FIG. 3a. Next, referring to FIG. 3b, a carbon-doped oxide liner layer 112 is formed conformally on the above structure of FIG. 3a, wherein the carbon-doped oxide liner layer has a thickness of 200˜700 nm. Next, referring to FIG. 3c, the carbon-doped oxide liner layer 112 is etched to form a carbon-doped oxide collar structure 112a, exposing the top surfaces of the dielectric layer 111 and the first electrode 103. Particularly, the carbon-doped oxide collar structure 112a surrounds an opening 113. Next, referring to FIG. 3d, a phase change material layer 114 is formed into the opening 113, and a second electrode 107 is formed thereon, electrically connecting to the phase change material layer 114.

Moreover, after the process as disclosed in FIG. 3c, a phase change material pillar 114 as disclosed in FIGS. 2a˜2c can be formed to replace the phase change material layer as disclosed in FIG. 3d. Finally, a carbon-doped oxide layer 112a is filled into the opening surrounded by the phase change material pillar 114, as shown in FIG. 4.

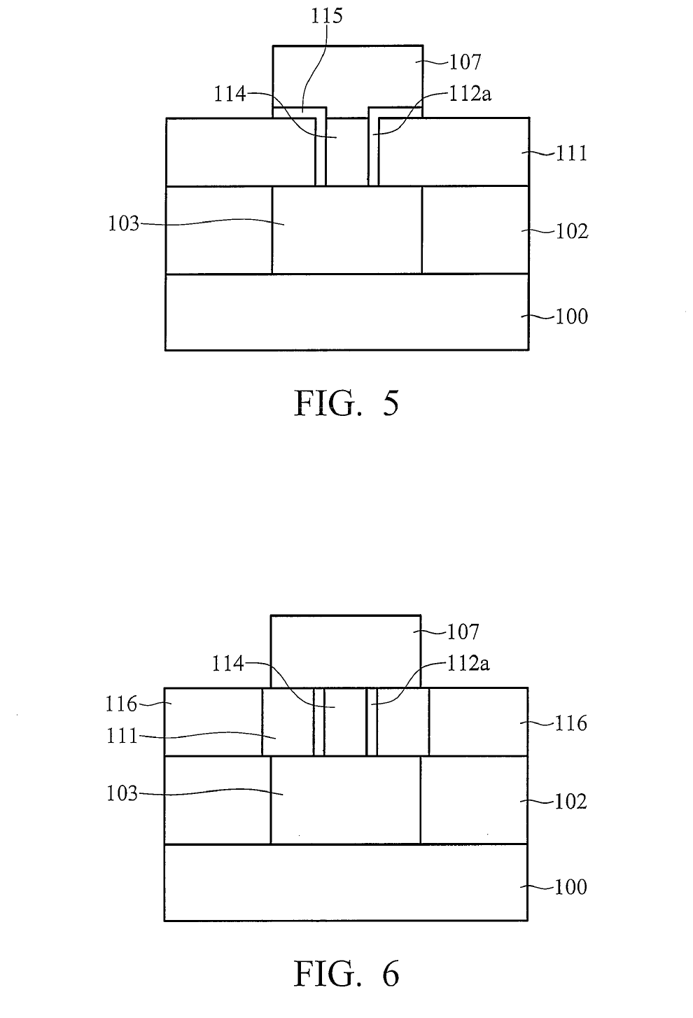

According to yet another embodiment of the invention, the carbon-doped oxide liner layer 112a can further comprise an extension part 115 to cover a part of the top surface of the dielectric layer 111, as shown in FIG. 5, and thereby reduce heat loss to surrounding areas. The extension part 115 can also be formed to cover a part of the bottom surface of the dielectric layer 111.

According to still another embodiment of the invention, referring to FIG. 6, the phase change material layer 116 with low thermal conductivity is substituted for the dielectric layer 111 in order to reduce the heat loss to surrounding areas. It should be noted that the phase change material layer 116 cannot be located to directly contact with the first electrode and second electrode.

In the embodiments of the invention, the phase-change memory element comprises a carbon-doped oxide layer with low thermal conductivity material surrounding and covering the side walls of the phase change material. Therefore, the disclosed phase-change memory element allows reduction of both programming current and programming voltage, since the required Joule heating is reduced. Further, since the required programming current density is reduced, reliability is also enhanced.

Moreover, since the phase change memory element exhibits good thermal uniformity within the active region of the cell, phase transformation speed is improved.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase-change memory element, comprising
a first electrode and a second electrode;
a first phase-change material layer formed between the first electrode and the second electrode, wherein the first electrode electrically connects the second electrodes via the phase-change material layer.; and
a carbon-doped oxide dielectric layer covering the side walls of the first phase-change material layer.

2. The phase-change memory element as claimed in claim 1, wherein the first phase-change material layer comprises chalcogenide.

3. The phase-change memory element as claimed in claim 1, wherein the first electrode or the second electrode comprises TaN, W, TiN, or TiW.

4. The phase-change memory element as claimed in claim 1, wherein the first electrode is a bottom electrode and the second electrode is a top electrode, wherein the first phase-change material layer directly contacts the first and second electrode.

5. The phase-change memory element as claimed in claim 1, wherein the contact interface between the first phase-change material layer and the first electrode and the contact interface between the first phase-change material layer and the second electrode are less than the resolution limit of photolithography process.

6. The phase-change memory element as claimed in claim 1, wherein the carbon-doped oxide dielectric layer has a thermal conductivity less than 0.4 W/m-k.

7. The phase-change memory element as claimed in claim 1, wherein the carbon-doped oxide dielectric layer comprises carbon-doped silicon oxide.

8. The phase-change memory element as claimed in claim 1, wherein the carbon-doped oxide dielectric layer contacts to the first electrode or the second electrode and comprises a collar structure.

9. The phase-change memory element as claimed in claim 1, further comprising:
a dielectric layer surrounding the carbon-doped oxide dielectric layer.

10. The phase-change memory element as claimed in claim 9, further comprising:
a second phase change material layer formed outside the dielectric layer and which does not directly contact with the first electrode and the second electrode.

11. The phase-change memory element as claimed in claim 1, wherein the carbon-doped oxide dielectric layer comprises a liner layer with a thickness of 200˜700 nm.

12. A phase-change memory element, comprising:
a bottom electrode and a top electrode;
a first phase-change material layer formed between the bottom electrode and top electrode, wherein the bottom electrode is electrically connected to the top electrode via the first phase-change material layer; and
a carbon-doped silicon oxide layer surrounding the first phase-change material layer and covering the side walls of the first phase-change material layer.

13. The phase-change memory element as claimed in claim 12, wherein the first phase-change material layer comprises chalcogenide.

14. The phase-change memory element as claimed in claim 12 wherein the bottom electrode or the top electrode comprises TaN, W, TiN, or TiW.

15. The phase-change memory element as claimed in claim 12, wherein the contact interface between the first phase-change material layer and the bottom electrode and the contact interface between the first phase-change material layer and the top electrode are less than the resolution limit of photolithography process.

16. The phase-change memory element as claimed in claim 12, wherein the carbon-doped silicon oxide layer has a thermal conductivity less than 0.4 W/m-k.

17. The phase-change memory element as claimed in claim 12, wherein the carbon-doped silicon oxide layer contacts to the bottom electrode or the top electrode and comprises a collar structure.

18. The phase-change memory element as claimed in claim 12, further comprising:
a dielectric layer surrounding the carbon-doped silicon oxide layer.

19. The phase-change memory element as claimed in claim 18, further comprising:
a second phase change material layer formed outside the dielectric layer and which does not directly contact with the bottom electrode and the top electrode.

20. The phase-change memory element as claimed in claim 1, wherein the carbon-doped silicon oxide layer comprises a liner layer with a thickness of 200˜700 nm.
